(19) United States
(12) Patent Application Publication
(10) Pub. No.: US 2022/0071193 A1
(43) Pub. Date: Mar. 10, 2022

(54) AN ANIMAL CAPTURE SYSTEM

(71) Applicant: Bayer Aktiengesellschaft, Leverkusen (DE)

(72) Inventors: Gilbert SPICA, Chazay D Azergues (FR); Renaud PAUMELIN, Lyon (FR)

(73) Assignee: Bayer Aktiengesellschaft, Leverkusen (DE)

(21) Appl. No.: 17/430,051

(22) PCT Filed: Feb. 6, 2020
(86) PCT No.: PCT/EP2020/052950

§ 371 Date: Aug. 11, 2021

(30) Foreign Application Priority Data
Feb. 18, 2019 (EP) 19157707.1

(51) Int. Cl. A01M 23/20; H03K 17/95

(52) U.S. Cl. CPC A01M 23/20; H03K 17/9505

(57) ABSTRACT

An animal trap system comprises a cage, a door, a switch system, a transmitter, a proximity signal sensor, and a proximity signal emitter. When the door is in a closed position, the door is configured to block the opening of the cage to prevent exit of the animal. When the door is in the open position the proximity signal emitter is at a position such that a magnitude of a proximity signal emitted by the proximity signal emitter and sensed by the proximity signal sensor is configured to maintain the transmitter in a non-transmitting mode. When the door is in the closed position the proximity signal emitter is at a position such that the magnitude of the proximity signal emitted by the proximity signal emitter and sensed by the proximity signal sensor is configured to cause the transmitter to transmit a signal that the cage is occupied.

### CROSS REFERENCE TO RELATED APPLICATIONS

This application is a national stage application under 35 U.S.C. § 371 of International Application No. PCT/EP2020/052950, filed internationally on Feb. 6, 2020, which claims the benefit of priority to European Application No. 19157707.1 filed Feb. 18, 2019.

### FIELD OF THE INVENTION

The present disclosure relates to an animal capture system and to a method for capturing an animal.

### BACKGROUND OF THE INVENTION

The general background of this disclosure is capture of animals that for example can be invasive alien species. For example, coypus and muskrats and American mink are not native to Europe, with coypus being native to subtropical and temperate South America and muskrats being native to North America. However, coypus, muskrats and mink can be disruptive to the environment in which they live, leading to erosion of riverbanks due to proliferation of burrows and the displacement of native species. These disruptive species can be primary carriers and vectors of disease; for example leptospirosis that is potentially transmissible to humans and that can be fatal, and which is responsible for miscarriages in cows who have consumed water from contaminated ponds, swamps or rivers. These disruptive species can be classified as pests, and climate change leading to warmer winters has led to an increase in numbers, not mitigated by natural predators, leading to an intolerable increase in the damage they cause. These animals therefore need to be controlled. Trapping to capture animals can form one control mechanism, however such control is labour intensive.

### SUMMARY OF THE INVENTION

It would be advantageous to have an improved way of capturing an animal.

According to some embodiments, in a first aspect, there is provided an animal capture system, comprising:

a cage;

a door;

a switch system;

a transmitter;

a proximity signal sensor; and

a proximity signal emitter.

The door is moveable with respect to the cage. When the door is in an open position an opening of the cage is suitable for the entry into the cage of an animal that is the size of a coypu. When the door is in a closed position, the door is configured to block the cage to prevent exit of the animal from the cage. The cage is configured to contain an animal bait within the cage. The switch system comprises a door closing mechanism. The switch system is configured to close the door when the animal has entered the cage. The transmitter is attached to the cage or placed securely in proximity to the cage. The proximity signal emitter is connected to the door. The proximity signal sensor is communicatively connected to the transmitter or is comprised within the transmitter. The proximity signal sensor is located at a position attached to the cage or located at a position placed securely in proximity to the cage. When the door is in the open position the proximity signal emitter is at a position with respect to the proximity signal sensor such that a magnitude of a proximity signal emitted by the proximity signal emitter and sensed by the proximity signal sensor is configured to maintain the transmitter in a non-transmitting mode. When the door is in the closed position the proximity signal emitter is at a position with respect to the proximity signal sensor such that the magnitude of the proximity signal emitted by the proximity signal emitter and sensed by the proximity signal sensor is configured to cause the transmitter to transmit a signal that the cage is occupied.

In other words, when an animal such as a coypu enters the cage to eat the bait, the door of the cage is triggered to close. As the door closes a proximity signal changes such that the transmitter transmits a signal that the animal has been caught. The transmitter can be attached to the cage or securely attached in proximity to the cage, such that the transmitter does not move relative to the cage.

The proximity signal can reduce in magnitude in order to trigger transmission, or increase in magnitude to trigger transmission.

Thus, when the proximity signal changes sufficiently a relay or switch of the transmitter is closed and the transmitter uses an aerial to transmit a signal that the cage is occupied. The aerial can be within the housing of the transmitter or external to the housing of the transmitter. A user can utilize for example an app on their mobile phone, where the mobile phone receives the transmitted signal and the app notifies to the user that the cage is occupied for example through an appropriate message appearing on the screen of the mobile phone, and/or through an alert sound or message being sounding from a speaker of the mobile phone.

In this way, a user can know in an easy and convenient way when traps have been triggered. Obligatory checking of traps, which can be for example daily before noon, can be simplified. Thus, a user will not have to make daily checks of cages, thereby saving time and resource. For example, a user can operate and maintain a greater number of traps (animal capture systems) according to the present invention. Furthermore, survival rates of trapped animals can be increased.

Furthermore, the trap can be easily reset and existing traps can be retrofitted to become an animal capture system.

In an example, when the door moves from the open position to the closed position the proximity signal emitter is moved away from the proximity signal sensor such that the magnitude of the proximity signal sensed by the proximity signal sensor is reduced below a threshold value. The transmitter is configured to transmit the signal that the cage is occupied when the magnitude of the proximity signal sensed by the proximity signal sensor falls below the threshold value.

Thus, for example the proximity signal sensor can be on the top of the cage and the proximity signal emitter that is attached to the cage door can be next to the proximity signal sensor when the door is open. As the door closes, the proximity signal emitter moves away from the proximity signal sensor until the signal detected falls below a threshold value and the transmitter begins to transmit.

In an example, when the door moves from the open position to the closed position the proximity signal emitter is moved toward the proximity signal sensor such that the magnitude of the proximity signal sensed by the proximity signal sensor is increased above a threshold value. The transmitter is configured to transmit the signal that the cage is occupied when the magnitude of the proximity signal sensed by the proximity signal sensor rises above the threshold value.

Thus, for example the proximity signal sensor can be on at the bottom of the cage next to the opening and the proximity signal emitter that is attached to the cage door can be next to the proximity signal sensor when the door is closed. However, when the door is open the proximity signal sensor is then positioned away from the proximity signal such that the signal detected is not sufficient to trigger the transmitter to start detecting. Then, as the door closes, the proximity signal emitter is moved toward the proximity signal sensor until the signal detected rises above a threshold value and the transmitter begins to transmit.

In an example, the proximity signal emitter is a magnet.

In this way a simple means is provided to trigger the system, where proximity signal sensor is configured to detect magnetic flux or a magnetic field.

In an example, a part of the door at a position where the proximity signal emitter is connected comprises a material to which the magnet is attracted.

In this way, a simple means is provide for attaching the proximity signal emitter to the door of a trap is provided, where that door is made from for example a ferrous material such as iron or steel.

In an example, the proximity signal emitter is detachable from the door.

In this way a normal cage can be retrofitted, because the proximity signal emitter is detachable and attachable or connectable to the door.

In an example, the transmitter comprises a receiver configured to receive a signal from a user.

In an example, the transmitter is configured to re-transmit the signal that the cage is occupied on receipt of a query from the user.

In an example, the transmitter comprises a GPS unit.

In this way, a user can be given location information, when the cage is determined to be occupied thereby facilitating checking and recovery of the cage.

Also, an anti-theft technology is provided, because in an example the user can send a query and be provided with a location of the cage, thereby facilitating recovery of a stolen cage with its transmitter.

Thus, a user for example can access a wen app or smart phone app, and report that the cage with transmitter or just the transmitter has been stolen. An appropriate signal can be sent to the transmitter that then starts to (periodically) report its position, facilitating recovery of the stolen property by the user and/or appropriate police personnel.

In an example, the signal transmitted that the cage is occupied comprises location information.

In an example, in response to a query received from the user, the transmitter is configured to transmit at least one location signal.

In an example, the transmitter is configured such that the at least one location signal is transmitted periodically.

In an example, the transmitter comprises an infrared movement sensor configured to detect movement within the cage, and wherein the signal transmitted that the cage is occupied comprises cage occupancy information.

In other words, a presence detection system is also provided, that can operate for example when the door has closed—thereby saving power.

In this way, when the cage is triggered a signal that the cage is occupied can include movement information. Thus, if there is no movement information, a user can determine that there is a false alarm and can schedule a return to the cage in an appropriate manner in order to reset the cage. However, if the movement information confirms that the cage is occupied, the user can act appropriately. Indeed, the movement information can be used to determine the type of animal likely to be in the case from its movement information. This could indicate that a target animal has indeed been caught, or could indicate that a non-target animal such as a cat or an endangered species animal has been caught, in which case the user can initiate immediate action to visit the cage.

In an example, in response to a query received from the user, the transmitter is configured to transmit an occupancy information signal.

According to some embodiments, in a second aspect, there is provided a method for capturing an animal, comprising:

a) moving a door of a cage to an open position, wherein when the door is in an open position an opening of the cage is suitable for the entry into the cage of an animal that is the size of a coypu; and wherein, when the door is in a closed position, the door blocks the cage to prevent exit of the animal from the cage;

b) containing an animal bait within the cage; wherein a switch system comprises a door closing mechanism; and wherein the switch system is configured to close the door when the animal has entered the cage;

c) attaching a transmitter to the cage or placing the transmitter securely in proximity to the cage;

d) connecting a proximity signal emitter to the door;

e) locating (250) a proximity signal sensor at a position attached to the cage or locating the proximity signal sensor at a position placed securely in proximity to the cage, wherein the proximity signal sensor is communicatively connected to the transmitter or is comprised within the transmitter; wherein when the door is in the open position the proximity signal emitter is at a position with respect to the proximity signal sensor such that a magnitude of a proximity signal emitted by the proximity signal emitter and sensed by the proximity signal sensor is configured to maintain the transmitter in a non-transmitting mode; and wherein when the door is in the closed position the proximity signal emitter is at a position with respect to the proximity signal sensor such that the magnitude of the proximity signal emitted by the proximity signal emitter and sensed by the proximity signal sensor is configured to cause the transmitter to transmit a signal that the cage is occupied.

In an example, the method comprises moving the door from the open position to the closed position and moving the proximity signal emitter away from the proximity signal sensor such that the magnitude of the proximity signal sensed by the proximity signal sensor is reduced below a threshold value, and transmitting the signal that the cage is occupied when the magnitude of the proximity signal sensed by the proximity signal sensor falls below the threshold value.

In an example, the method comprises moving the door from the open position to the closed position and moving the proximity signal emitter toward the proximity signal sensor such that the magnitude of the proximity signal sensed by the proximity signal sensor is increased above a threshold value, and transmitting the signal that the cage is occupied when the magnitude of the proximity signal sensed by the proximity signal sensor rises above the threshold value.

Advantageously, the benefits provided by any of the above aspects equally apply to all of the other aspects and vice versa.

The above aspects and examples will become apparent from and be elucidated with reference to the embodiments described hereinafter.

### BRIEF DESCRIPTION OF THE DRAWINGS

Exemplary embodiments will be described in the following with reference to the following drawings:

FIG. 1 shows a schematic set up of an example of an animal capture system with an open door;

FIG. 2 shows a schematic set up of an example of an animal capture system with a closed door; and

FIG. 3 shows a method for capturing an animal.

### DETAILED DESCRIPTION OF EMBODIMENTS

FIG. 1 shows an example of an animal capture system 10. The animal capture system comprises a cage 20, a door 30, a switch system 80, a transmitter 50, a proximity signal sensor 60, a proximity signal emitter (70). The door is moveable with respect to the cage. When the door is in an open position an opening of the cage is suitable for the entry into the cage of an animal that is the size of a coypu. When the door is in a closed position, the door is configured to block the cage to prevent exit of the animal from the cage. The cage is configured to contain an animal bait within the cage. The switch system comprises a door closing mechanism. The switch system is configured to close the door when the animal has entered the cage. The transmitter is attached to the cage or it can alternatively be placed securely in proximity to the cage. The proximity signal emitter is connected to the door. The proximity signal sensor is communicatively connected to the transmitter or is comprised within the transmitter. The proximity signal sensor is located at a position attached to the cage or it can alternatively be located at a position placed securely in proximity to the cage. When the door is in the open position the proximity signal emitter is at a position with respect to the proximity signal sensor such that a magnitude of a proximity signal emitted by the proximity signal emitter and sensed by the proximity signal sensor is configured to maintain the transmitter in a non-transmitting mode. When the door is in the closed position the proximity signal emitter is at a position with respect to the proximity signal sensor such that the magnitude of the proximity signal emitted by the proximity signal emitter and sensed by the proximity signal sensor is configured to cause the transmitter to transmit a signal that the cage is occupied.

In an example, the transmitter is configured to be powered by at least one battery.

In an example, the proximity signal sensor is configured to be powered by at least one battery.

In an example, the animal capture system is configured to be powered for at least one year by the at least one battery.

In an example, the animal capture system is configured to enter an activated state upon the pressing of a button. In an example, the transmitter comprises the button.

In an example, the transmitter is detachable from the cage. Thus, a normal cage can be transformed into an animal capture system as described here.

In an example, a casing of the transmitter is made from plastic.

In an example, the transmitter is configured for long range communication. In an example, the transmitter is configured for low bit rate communication. In this manner, the system finds excellent utility in rural environments.

In an example, the transmitted signal comprises an SMS. In an example, the transmitted signal comprises an email.

According to an example, when the door moves from the open position to the closed position the proximity signal emitter is moved away from the proximity signal sensor such that the magnitude of the proximity signal sensed by the proximity signal sensor is reduced below a threshold value. The transmitter is configured to transmit the signal that the cage is occupied when the magnitude of the proximity signal sensed by the proximity signal sensor falls below the threshold value. Thus, as shown in FIG. 1 the proximity signal sensor can be mounted on the cage and when the door is open the proximity signal emitter that is connected to the door can be adjacent to the sensor and the sensed signal is high, and the transmitter does not transmit. Then, when the door closes the emitter moves away from the sensor, and the sensed magnitude of the signal falls, proportional to the square of the distance moved, and when the signal falls below a threshold the transmitter starts to transmit.

According to an example, when the door moves from the open position to the closed position the proximity signal emitter is moved toward the proximity signal sensor such that the magnitude of the proximity signal sensed by the proximity signal sensor is increased above a threshold value. The transmitter is then configured to transmit the signal that the cage is occupied when the magnitude of the proximity signal sensed by the proximity signal sensor rises above the threshold value. Thus, this example is not shown in FIG. 1 but is discussed above. Thus, the proximity signal sensor could be mounted on the side of the cage toward the bottom front edge of the cage opening or mounted securely on the ground next to the door opening. The proximity signal emitter can then be mounted on the bottom of the door, for example. When the door is in the open position the sensor is spaced from the emitter and the sensed signal is low and even zero, and this low signal or lack of signal is configured to stop the transmitter from transmitting a signal that the cage is occupied. However, when an animal enters the cage and the trap is sprung, and the door closes the emitter is moved towards the sensor as the door closes. The signal increases in proportion to the square of the decreasing distance between the emitter and sensor and at a threshold value the sensed signal is great enough to trigger the transmitter to start transmitting a signal that the cage is occupied.

In an example, the transmitter is configured periodically to transmit a signal that the animal capture system is functional. In an example, the transmitter is configured daily to transmit a signal that the animal capture system is functional.

In an example, the switch system that triggers the door to close when an animal enters the cage is a standard switch system found on other traps that trigger the door to similarly close when an animal enters the trap.

In an example, the transmitter is configured to transmit a signal that the animal capture system is activated when the door is in the open position. Thus, a relay or switch of the transmitter is activated and the transmitter uses an aerial to transmit a signal that the cage is activated. The relay or switch that is used in indicating that the cage is active can be the same as that used to indicate that the cage is occupied. However, a different switch or relay can be used to indicate that the cage is activated to that used to indicate that the cage is occupied. Thus, a user can have a mobile telephone with an app, and the mobile phone can receive the signal and the app notify to the use that the cage is activated, and in this way the use can be sure that the cage is correctly set or primed. The part of the transmitter that is configured to transmit a signal that the cage has been activated can be the same as the part of the transmitter that periodically (i.e., daily) transmits a signal that the cage is functional.

In an example, the aerial or antenna is located within the transmitter.

In an example, the transmitter can be battery powered. In some examples, where a power outlet is nearby the transmitter can be mains powered, powered via an appropriate transformer.

In an example, the transmitter is configured to transmit using Sigfox technology. In an example, a signal can be transmitted to a Sigfox server in order that a user can receive a message (that the cage is occupied, optionally that the cage is activated, and optionally that the cage remains operational). Other transmission technologies can be utilized that also provide energy savings.

According to an example, the proximity signal emitter is a magnet.

According to an example, a part of the door at a position where the proximity signal emitter is connected comprises a material to which the magnet is attracted.

According to an example, the proximity signal emitter is detachable from the door.

According to an example, the transmitter comprises a receiver 90, configured to receive a signal from a user.

In an example, the animal capture system is configured to enter an activated state upon receipt of an appropriate signal from a user.

In an example, a user can use a web app to communicate with the animal capture system.

In an example, a user can use a smart phone app to communicate with the animal capture system.

According to an example, the transmitter is configured to re-transmit the signal that the cage is occupied on receipt of a query from the user.

According to an example, the transmitter comprises a GPS unit 100.

According to an example, the signal transmitted that the cage is occupied comprises location information.

According to an example, in response to a query received from the user, the transmitter is configured to transmit at least one location signal.

According to an example, the at least one location signal is transmitted periodically.

According to an example, the transmitter comprises an infrared movement sensor 110 configured to detect movement within the cage, and wherein the signal transmitted that the cage is occupied comprises cage occupancy information.

In an example, a radar sensor is used instead of, or the IR sensor. In an example the IR sensor is an active sensor emitting a beam of IR radiation, from an LED or laser, which is detected. In an example, the IR movement sensor is a passive IR sensor.

According to an example, in response to a query received from the user, the transmitter is configured to transmit an occupancy information signal.

In an example, the system complies with IP67 requirements. Thus, the system is robust and can be temporarily submersed in water.

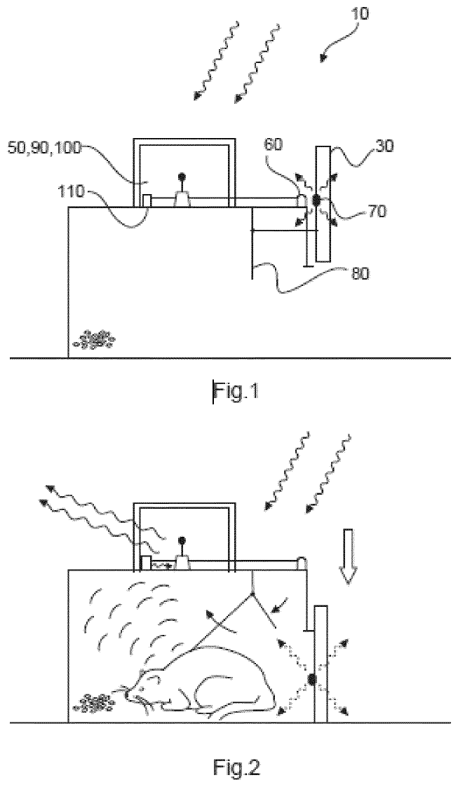

Thus, as shown in FIG. 2, in a specific example of the animal capture system when an animal has entered the case, the door has been triggered to close, and the transmitter starts to transmit as the emitter has moved away from the sensor and the signal detected or sensed has fallen below a threshold. At the same time an IR movement sensor has detected movement. Thus, the signal transmitted indicates that the door has closed and that there is an animal within the cage. The movement signature has been analyzed to indicate that the captured animal is probably a Coypu, and the information that there is an animal in the cage with the door closed and that it is probably a Coypu is transmitted. Within the transmitted signal is also the location of the cage and transmitter derived from a GPS unit housed within the transmitter, along with a time stamp of when the cage closure was triggered. The transmitted signal will now be retransmitted every 15 minutes, and a user can receive that signal via SMS, an email and even log onto an APP top see details of the cage and it occupied/unoccupied status, along with an indication of the type of animal probably within the cage.

Furthermore, as shown in FIGS. 1-2, a query signal was received by the animal capture system to assess its status, and the transmitter transmitted its location along with an indication that it was empty with respect to FIG. 1. A later query was sent by the user who had not picked up their emails, and the transmitter immediately transmitted that the cage was occupied as shown in FIG. 2. The transmitter had already sent that transmission when the trap was triggered, but the user having not looked at their emails did not receive that notice, but by querying the system via a smart phone app they were able to receive an indication of the trap status, without having to open their email account.

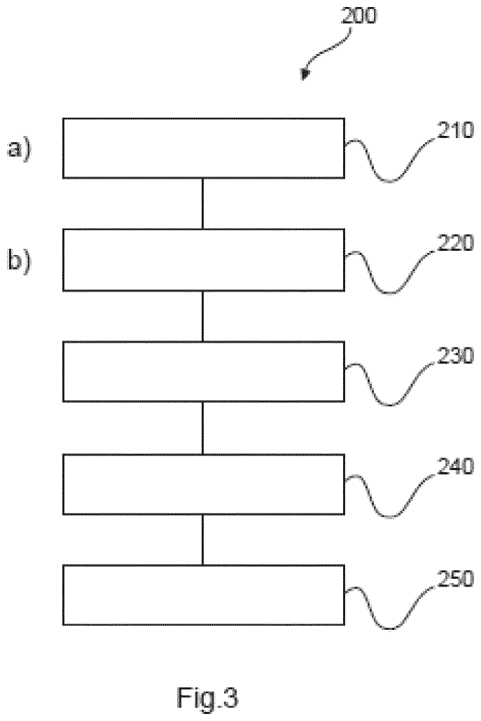

FIG. 3 shows an example of a method 200 for capturing an animal. The method comprises:

in a moving step 210, also referred to as step a), moving a door of a cage to an open position, wherein when the door is in an open position an opening of the cage is suitable for the entry into the cage of an animal that is the size of a coypu; and wherein, when the door is in a closed position, the door blocks the cage to prevent exit of the animal from the cage;

in a containing step 220, also referred to as step b), containing an animal bait within the cage; wherein a switch system comprises a door closing mechanism; and wherein the switch system is configured to close the door when the animal has entered the cage;

in an attaching step 230, also referred to as step c), attaching a transmitter to the cage or placing the transmitter securely in proximity to the cage;

in a connecting step 240, also referred to as step d), connecting a proximity signal emitter to the door;

in a locating step 250, also referred to as step e), locating a proximity signal sensor at a position attached to the cage or locating the proximity signal sensor at a position placed securely in proximity to the cage, wherein the proximity signal sensor is communicatively connected to the transmitter or is comprised within the transmitter; wherein when the door is in the open position the proximity signal emitter is at a position with respect to the proximity signal sensor such that a magnitude of a proximity signal emitted by the proximity signal emitter and sensed by the proximity signal sensor is configured to maintain the transmitter in a non-transmitting mode; and wherein when the door is in the closed position the proximity signal emitter is at a position with respect to the proximity signal sensor such that the magnitude of the proximity signal emitted by the proximity signal emitter and sensed by the proximity signal sensor is configured to cause the transmitter to transmit a signal that the cage is occupied.

According to an example, the method comprises moving the door from the open position to the closed position and moving the proximity signal emitter away from the proximity signal sensor such that the magnitude of the proximity signal sensed by the proximity signal sensor is reduced below a threshold value, and transmitting the signal that the cage is occupied when the magnitude of the proximity signal sensed by the proximity signal sensor falls below the threshold value.

According to an example, the method comprises moving the door from the open position to the closed position and moving the proximity signal emitter toward the proximity signal sensor such that the magnitude of the proximity signal sensed by the proximity signal sensor is increased above a threshold value, and transmitting the signal that the cage is occupied when the magnitude of the proximity signal sensed by the proximity signal sensor rises above the threshold value.

In an example, the proximity signal emitter is a magnet.

In an example, a part of the door at a position where the proximity signal emitter is connected comprises a material to which the magnet is attracted.

In an example, the proximity signal emitter is detachable from the door.

In an example, the transmitter comprises a receiver, configured to receive a query signal from a user.

In an example, the transmitter is configured to re-transmit the signal that the cage is occupied on receipt of a query from the user.

In an example, the transmitter comprises a GPS unit.

In an example, the signal transmitted that the cage is occupied comprises location information.

In an example, in response to a query received from the user, the transmitter is configured to transmit at least one location signal.

In an example, the at least one location signal is transmitted periodically.

In an example, the transmitter comprises an infrared movement sensor configured to detect movement within the cage, and wherein the signal transmitted that the cage is occupied comprises cage occupancy information.

In an example, in response to a query received from the user, the transmitter is configured to transmit an occupancy information signal.

In an example, the animal food comprises a dehydrated food. In an example, the animal food comprises carrot. In an example, the animal food comprises parsnip. In an example, the animal food comprises a mixture of dehydrated carrot and dehydrated parsnip. In an example, the animal food comprises a mixture of 50% carrot and 50% parsnip. In this way, the food will last longer before perishing or deteriorating, reducing the frequency of re-visits to the trap. Such dehydrated foods can in certain situations last for 8 to 10 days, thereby enabling a cage to be primed and left for a long duration before having to be checked when a signal has indicated that the cage is occupied, or after a prolonged period when the food needs to be refreshed.

In an example, a first dimension of the animal food is bigger than a dimension of a mesh of the cage. In this way, a food such as dehydrated or dried vegetables does not fall through the gaps in the cage, but stays in place and does not fall under the cage. In an example, a second dimension of the animal food orthogonal to the first dimension is bigger that the dimension of the mesh of the cage. In an example, a third dimension of the animal food orthogonal to the first dimension and orthogonal to the second dimension is bigger than the dimension of the mesh of the cage.

It has to be noted that embodiments of the invention are described with reference to different subject matters. In particular, some embodiments are described with reference to method type claims whereas other embodiments are described with reference to the device type claims. However, a person skilled in the art will gather from the above and the following description that, unless otherwise notified, in addition to any combination of features belonging to one type of subject matter also any combination between features relating to different subject matters is considered to be disclosed with this application. However, all features can be combined providing synergetic effects that are more than the simple summation of the features.

While the invention according to some embodiments has been illustrated and described in detail in the drawings and foregoing description, such illustration and description are to be considered illustrative or exemplary and not restrictive. The invention is not limited to the disclosed embodiments. Other variations to the disclosed embodiments can be understood and effected by those skilled in the art in practicing a claimed invention, from a study of the drawings, the disclosure, and the dependent claims.

In the claims, the word “comprising” does not exclude other elements or steps, and the indefinite article “a” or “an” does not exclude a plurality. A single processor or other unit may fulfill the functions of several items re-cited in the claims. The mere fact that certain measures are re-cited in mutually different dependent claims does not indicate that a combination of these measures cannot be used to advantage. Any reference signs in the claims should not be construed as limiting the scope.

1. An animal capture system, comprising:
a cage;
a door;
a switch system;
a transmitter;
a proximity signal sensor; and
a proximity signal emitter;
wherein the door is moveable with respect to the cage;
wherein when the door is in an open position an opening of the cage is suitable for the entry into the cage of an animal that is the size of a coypu;
wherein when the door is in a closed position, the door is configured to block the cage to prevent exit of the animal from the cage;
wherein the cage is configured to contain an animal bait within the cage;
wherein the switch system comprises a door closing mechanism;
wherein the switch system is configured to close the door when the animal has entered the cage;
wherein the transmitter is attached to the cage or placed securely in proximity to the cage;
wherein the proximity signal emitter is connected to the door;
wherein the proximity signal sensor is communicatively connected to the transmitter or is comprised within the transmitter;
wherein the proximity signal sensor is located at a position attached to the cage or located at a position placed securely in proximity to the cage;
wherein when the door is in the open position the proximity signal emitter is at a position with respect to the proximity signal sensor such that a magnitude of a proximity signal emitted by the proximity signal emitter and sensed by the proximity signal sensor is configured to maintain the transmitter in a non-transmitting mode; and
wherein when the door is in the closed position the proximity signal emitter is at a position with respect to the proximity signal sensor such that the magnitude of the proximity signal emitted by the proximity signal emitter and sensed by the proximity signal sensor is configured to cause the transmitter to transmit a signal that the cage is occupied.

2. The animal capture system of claim 1, wherein when the door moves from the open position to the closed position the proximity signal emitter is moved away from the proximity signal sensor such that the magnitude of the proximity signal sensed by the proximity signal sensor is reduced below a threshold value, and wherein the transmitter is configured to transmit the signal that the cage is occupied when the magnitude of the proximity signal sensed by the proximity signal sensor falls below the threshold value.

3. The animal capture system of claim 1, wherein when the door moves from the open position to the closed position the proximity signal emitter is moved toward the proximity signal sensor such that the magnitude of the proximity signal sensed by the proximity signal sensor is increased above a threshold value, and wherein the transmitter is configured to transmit the signal that the cage is occupied when the magnitude of the proximity signal sensed by the proximity signal sensor rises above the threshold value.

4. The animal capture system of claim 1, wherein the proximity signal emitter is a magnet.

5. The animal capture system of claim 4, wherein a part of the door at a position where the proximity signal emitter is connected comprises a material to which the magnet is attracted.

6. The animal capture system of claim 1, wherein the proximity signal emitter is detachable from the door.

7. The animal capture system of claim 1, wherein the transmitter comprises a receiver, wherein the receiver is configured to receive a signal from a user.

8. The animal capture system of claim 7, wherein the transmitter is configured to re-transmit the signal that the cage is occupied on receipt of a query from the user.

9. The animal capture system of claim 7, wherein the transmitter comprises a GPS unit.

10. The animal capture system of claim 9, wherein the signal transmitted that the cage is occupied comprises location information.

11. The animal capture system of claim 10, wherein in response to a query received from the user, the transmitter is configured to transmit at least one location signal.

12. The animal capture system of claim 11, wherein the at least one location signal is transmitted periodically.

13. The animal capture system of claim 7, wherein the transmitter comprises an infrared movement sensor configured to detect movement within the cage, and wherein the signal transmitted that the cage is occupied comprises cage occupancy information.

14. The animal capture system of claim 13, wherein in response to a query received from the user, the transmitter is configured to transmit an occupancy information signal.

15. A method for capturing an animal, comprising:
moving a door of a cage to an open position, wherein when the door is in an open position an opening of the cage is suitable for the entry into the cage of an animal that is the size of a coypu; and wherein when the door is in a closed position, the door blocks the cage to prevent exit of the animal from the cage;
containing an animal bait within the cage; wherein a switch system comprises a door closing mechanism; and wherein the switch system is configured to close the door when the animal has entered the cage;
attaching a transmitter to the cage or placing the transmitter securely in proximity to the cage;
connecting a proximity signal emitter to the door; and
locating a proximity signal sensor at a position attached to the cage or locating the proximity signal sensor at a position placed securely in proximity to the cage, wherein the proximity signal sensor is communicatively connected to the transmitter or is comprised within the transmitter; wherein when the door is in the open position the proximity signal emitter is at a position with respect to the proximity signal sensor such that a magnitude of a proximity signal emitted by the proximity signal emitter and sensed by the proximity signal sensor is configured to maintain the transmitter in a non-transmitting mode; and wherein when the door is in the closed position the proximity signal emitter is at a position with respect to the proximity signal sensor such that the magnitude of the proximity signal emitted by the proximity signal emitter and sensed by the proximity signal sensor is configured to cause the transmitter to transmit a signal that the cage is occupied.

16. The method of claim 15, comprising moving the door from the open position to the closed position and moving the proximity signal emitter away from the proximity signal sensor such that the magnitude of the proximity signal sensed by the proximity signal sensor is reduced below a threshold value, and transmitting the signal that the cage is occupied when the magnitude of the proximity signal sensed by the proximity signal sensor falls below the threshold value.

17. The method of claim 15, comprising moving the door from the open position to the closed position and moving the proximity signal emitter toward the proximity signal sensor such that the magnitude of the proximity signal sensed by the proximity signal sensor is increased above a threshold value, and transmitting the signal that the cage is occupied when the magnitude of the proximity signal sensed by the proximity signal sensor rises above the threshold value.
